(19) United States
(12) Patent Application Publication
(10) Pub. No.: US 2014/0176033 A1
(43) Pub. Date: Jun. 26, 2014

(54) DRIVING CIRCUIT, DRIVING MODULE, AND MOTOR DRIVING APPARATUS

(71) Applicant: SAMSUNG ELECTRO-MECHANICS CO., LTD., Suwon (KR)

(72) Inventors: Chang Jae HEO, Suwon (KR); Sung Man PANG, Suwon (KR)

(73) Assignee: SAMSUNG ELECTRO-MECHANICS CO., LTD., Suwon (KR)

(21) Appl. No.: 13/777,673

(22) Filed: Feb. 26, 2013

(30) Foreign Application Priority Data
Dec. 21, 2012 (KR) 10-2012-0150446

(51) Int. Cl. H03K 17/16

(52) U.S. Cl. CPC H03K 17/16
USPC 318/400.42; 327/383

(57) ABSTRACT

There is provided a driving circuit including: a signal delay unit including a first delay unit delaying a high level input signal in a case in which an input signal has a high level, and a second delay unit delaying a low level input signal when the input signal has a low level; a signal output unit including first and second transistors connected to the first and second delay units and performing a switching operation under the control of the first and second delay units, respectively; and an output holding unit maintaining an output voltage at a level equal to that immediately before the first and second transistors are turned off, when the first and second transistors are simultaneously turned off.

### CROSS-REFERENCE TO RELATED APPLICATIONS

This application claims the priority of Korean Patent Application No. 10-2012-0150446 filed on Dec. 21, 2012, in the Korean Intellectual Property Office, the disclosure of which is incorporated herein by reference.

### BACKGROUND OF THE INVENTION

1. Field of the Invention

The present invention relates to a driving circuit, a driving module, and a motor driving apparatus for canceling interference between driving signals for driving a power semiconductor device.

2. Description of the Related Art

In case of using a self turn-off type power semiconductor device such as insulated gate bipolar transistor (IGBT), or the like, in a driving circuit of a general power semiconductor device, gate driving signals for driving are provided to gates of a power semiconductor device, but here, a gate driving signal of a high-side power semiconductor device and a gate driving signal of a low-side power semiconductor device may interfere with each other, as disclosed in the related art document below.

Patent document 1 relates to a switching method using an IGBT module and an IGBT driving circuit therefor, devised to solve a problem of damage to an IGBT by preventing two IGBTs from being turned on simultaneously.

However, the patent document 1 does not disclose a driving circuit including a filter circuit canceling noise by maintaining an output voltage having a level such as which exists immediately before two transistors are turned off, when the two transistors are turned off, a driving module, and a motor driving apparatus.

### RELATED ART DOCUMENT

(Patent document 1) Korean Patent Laid Open Publication No. 10-2004-0023936

### SUMMARY OF THE INVENTION

An aspect of the present invention provides a driving circuit filtering low level noise superposed on a high signal input and high level noise superposed on a low signal input.

Another aspect of the present invention provides a driving module including the driving circuit.

Another aspect of the present invention provides a motor driving apparatus including the driving circuit.

According to an aspect of the present invention, there is provided a driving circuit including: a signal delay unit including a first delay unit delaying a high level input signal in a case in which an input signal has a high level, and a second delay unit delaying a low level input signal when the input signal has a low level; a signal output unit including first and second transistors connected to the first and second delay units and performing a switching operation under the control of the first and second delay units, respectively; and an output holding unit maintaining an output voltage at a level equal to that immediately before the first and second transistors are turned off, when the first and second transistors are simultaneously turned off.

The signal delay unit may further include at least one inverter inverting the input signal and providing the inverted signal to the first and second delay units.

The first delay unit may delay the input signal by an amount of time required for the first delay unit to have a voltage charged to reach a level equal to or higher than a pre-set high level voltage.

The second delay unit delays the input signal by an amount of time required for the second delay unit to have a voltage discharged to reach a level lower than a pre-set low level voltage.

The first and second delay units may further include at least one switching element, at least one inverter, and at least one delay element for generating a delay.

The output holding unit may include at least one inverter and at least one latch circuit.

According to another aspect of the present invention, there is provided a driving circuit including: a first inverter inverting an input signal; a first delay unit delaying a first signal received from the first inverter until a voltage of a first capacitor reaches a level equal to or higher than a pre-set high level; a second delay unit delaying a second signal received from the first inverter until when a voltage of a second capacitor is discharged to have a level lower than a pre-set low level; a signal output unit including first and second transistors connected to the first and second delay units and performing a switching operation under the control of the first and second delay units, respectively; and an output holding unit maintaining an output voltage at a level equal to that immediately before the first and second transistors are turned off when the first and second transistors are simultaneously turned off.

The first signal may be a low level signal, and the second signal may be a high level signal.

The first delay unit may control a turn-on operation of the first transistor by using the delayed first signal.

The second delay unit may control a turn-on operation of the second transistor by using the delayed second signal.

When the second signal is received from the first inverter, the first delay unit may control a turn-off operation of the first transistor without a delay.

When the first signal is received from the first inverter, the second delay unit may control a turn-off operation of the second transistor without a delay.

The first and second delay units may further include at least one switching element, at least one inverter, and at least one delay element for generating a delay, respectively.

The output holding unit may include at least one inverter and at least one latch circuit.

The at least one delay element may include a resistor connected to the second capacitor.

According to another aspect of the present invention, there is provided a driving module including: at least one driving circuit including a signal delay unit including a first delay unit delaying a high level input signal in a case in which an input signal has a high level, and a second delay unit delaying a low level input signal when the input signal has a low level, a signal output unit including first and second transistors connected to the first and second delay units and performing a switching operation under the control of the first and second delay units, respectively, and an output holding unit maintaining an output voltage at a level equal to that immediately before the first and second transistors are turned off, when the first and second transistors are simultaneously turned off; and a switching unit having a semiconductor element switched on and switched off according to a driving signal from the at least one driving circuit.

The switching unit may include at least two semiconductor elements stacked between an operating power source terminal and a ground.

The driving module may further include first and second driving circuits driving the semiconductor elements, respectively.

According to another aspect of the present invention, there is provided a motor driving apparatus including: a driving circuit group including a plurality of driving circuits each including a signal delay unit including a first delay unit delaying a high level input signal in a case in which an input signal has a high level, and a second delay unit delaying a low level input signal when the input signal has a low level, a signal output unit including first and second transistors connected to the first and second delay units and performing a switching operation under the control of the first and second delay units, respectively, and an output holding unit maintaining an output voltage at a level equal to that immediately before the first and second transistors are turned off, when the first and second transistors are simultaneously turned off; and an inverter driving a motor by using inverter arms included therein, each of the inverter arms having a semiconductor element switched on or switched off according to a driving signal from each of the plurality of driving circuits of the driving circuit group.

The inverter may include 3-phase inverter arms in which at least one first semiconductor element and at least one second semiconductor element are stacked, respectively.

The driving circuit group may include a plurality of high side driving circuits driving the first semiconductor elements of the 3-phase inverter arms, respectively; and a plurality of low side driving circuits driving the second semiconductor elements of the 3-phase inverter arms, respectively.

### BRIEF DESCRIPTION OF THE DRAWINGS

The above and other aspects, features and other advantages of the present invention will be more clearly understood from the following detailed description taken in conjunction with the accompanying drawings, in which:

FIG. 1 is a circuit diagram of a driving circuit according to an embodiment of the present invention;

FIG. 2 is a view illustrating operational waveforms of each part according to an embodiment of the present invention;

FIG. 3A is a view illustrating operational waveforms with respect to high noise in case in which an input signal has a low level;

FIG. 3B is a view illustrating operational waveforms with respect to low noise in a case in which an input signal has a high level;

FIG. 4 is a circuit diagram illustrating application examples of a signal delay unit according to an embodiment of the present invention;

FIG. 5 is a circuit diagram of a driving circuit according to another embodiment of the present invention;

FIG. 6 is a circuit diagram of a driving circuit according to another embodiment of the present invention;

FIG. 7 is a schematic view illustrating a configuration of a driving module according to an embodiment of the present invention; and

FIG. 8 is a schematic view illustrating a configuration of a motor driving apparatus according to an embodiment of the present invention.

### DETAILED DESCRIPTION OF THE PREFERRED EMBODIMENT

Hereinafter, embodiments will be described in detail with reference to the accompanying drawings such that they can be easily practiced by those skilled in the art to which the present invention pertains.

In describing the present invention, if a detailed explanation for a related known function or construction is considered to unnecessarily divert the gist of the present invention, such explanation will be omitted but would be understood by those skilled in the art.

Also, similar reference numerals are used for similar parts throughout the specification.

It will be understood that when an element is referred to as being “connected to” another element, it can be directly connected to the other element or intervening elements may also be present. In contrast, when an element is referred to as being “directly connected to” another element, no intervening elements are present.

In addition, unless explicitly described to the contrary, the word “comprise” and variations such as “comprises” or “comprising,” will be understood to imply the inclusion of stated elements but not the exclusion of any other elements.

Embodiments of the present invention will hereinafter be described in detail with reference to the accompanying drawings.

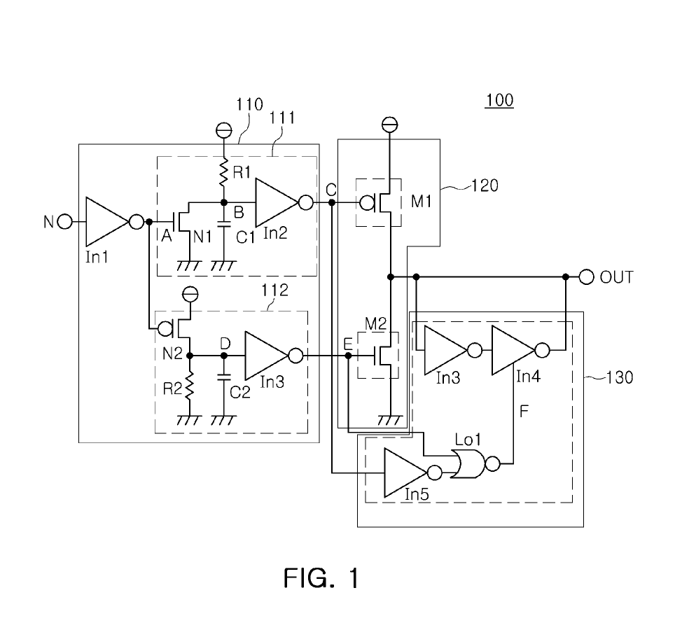

FIG. 1 is a circuit diagram of a driving circuit 100 according to an embodiment of the present invention.

Referring to FIG. 1, the driving circuit 100 according to an embodiment of the present invention may include a signal delay unit 110, a signal output unit 120, and an output holding unit 130.

The signal delay unit 110 may include a first delay unit 111 and a second delay unit 112. Also, the signal delay unit 110 may further include at least one inverter In1 inverting an input signal and providing the inverted signal to the first and second delay units 111 and 112, respectively.

For example, in the case in which the signal delay unit 110 is determined to have a single inverter, the first and second delay units 111 and 112 may be connected to the first inverter In1.

The first and second delay units 111 and 112 may include at least one switching element, at least one inverter, and at least one delay element for generating a delay.

The first delay unit 111 according to an embodiment of the present invention will be described with reference to FIG. 1. The first delay unit 111 may include a switching element N1 performing a switching operation upon receiving an inverted input signal from the first inverter In1, and at least one delay element connected to the switching element N1 and delaying the inverted input signal.

Here, the switching element N1 may be an NMOS transistor, and the at least one delay element may include a resistor R1, connected to a driving power source and a capacitor C1 connected to the resistor R1 in series.

The input signal delayed by the at least one delay element may be inverted by the second inverter In2, and subsequently provided to the signal output unit 120.

The second delay unit 112 according to an embodiment of the present invention will be described with reference to FIG. 1. The second delay unit 112 may include a switching element N2 performing a switching operation upon receiving an inverted input signal from the first inverter In1, and at least one delay element connected to the switching element N2 delaying the inverted input signal. Here, the switching element N2 may be a PMOS transistor, and the at least one delay element may include a resistor R2 connected in series to the switching element N2 and a capacitor C2 connected in parallel to the resistor R2.

The input signal delayed by the at least one delay element may be inverted by the third inverter In3, and subsequently provided to the signal output unit 120.

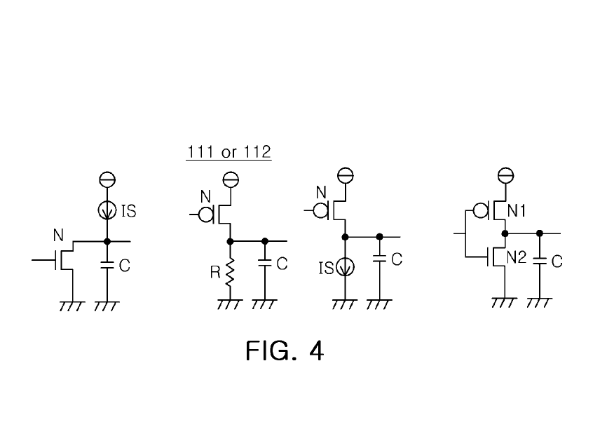

FIG. 4 is a circuit diagram illustrating application examples of the signal delay unit 110 according to an embodiment of the present invention. Referring to FIG. 4, the first and second delay units 111 and 112 may be applied as illustrated in FIG. 4. However, the first and second delay units 111 and 112 are not limited to the examples illustrated in FIG. 4.

When the input signal has a high level, the first delay unit 111 may delay the high level input signal. When the input signal has a low level, the second delay unit 112 may delay the low level input signal. Details of the signal delay unit 100 will be described below.

The signal output unit 120 may include a first transistor M1 and a second transistor M2. The first transistor M1 may perform a switching operation upon receiving an output signal from the first delay unit 111. The second transistor M2 may perform a switching operation upon receiving an output signal from the second delay unit 112.

Referring to FIG. 1, for example, the first transistor M1 may be a PMOS transistor, and the second transistor M2 may be an NMOS transistor.

Namely, the first transistor M1 may be connected to the first delay unit 111 and turned on or turned off under the control of the first delay unit 111. The second transistor M2 may be connected to the second delay unit 112 and turned on or turned off under the control of the second delay unit 112.

When the first and second transistors M1 and M2 are simultaneously turned off, the output holding unit 130 may maintain an output voltage at a level equal to that immediately before the first and second transistors M1 and M2 were turned off. The output holding unit 130 may include at least one inverter In3, In4, and In5 and at least one latch circuit Lo1. Here, the latch circuit Lo1 may be, for example, a NOR latch circuit.

Namely, in a case in which the first and second transistors M1 and M2 are simultaneously turned off, the output voltage having the level equal to that immediately before the first and second transistors M1 and M2 were turned off is maintained, thereby obtaining a technical effect of canceling noise of a superposed on a low level signal when the input signal has a high level, and canceling noise of a superposed on a high level signal.

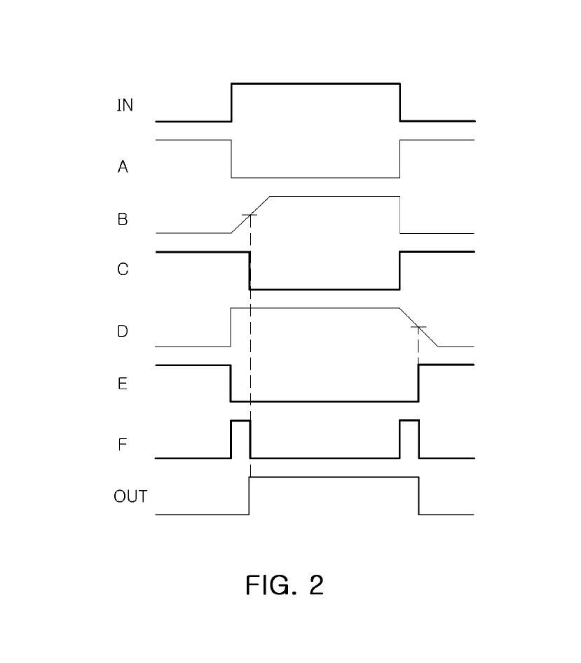

FIG. 2 is a view illustrating operational waveforms of each part according to an embodiment of the present invention.

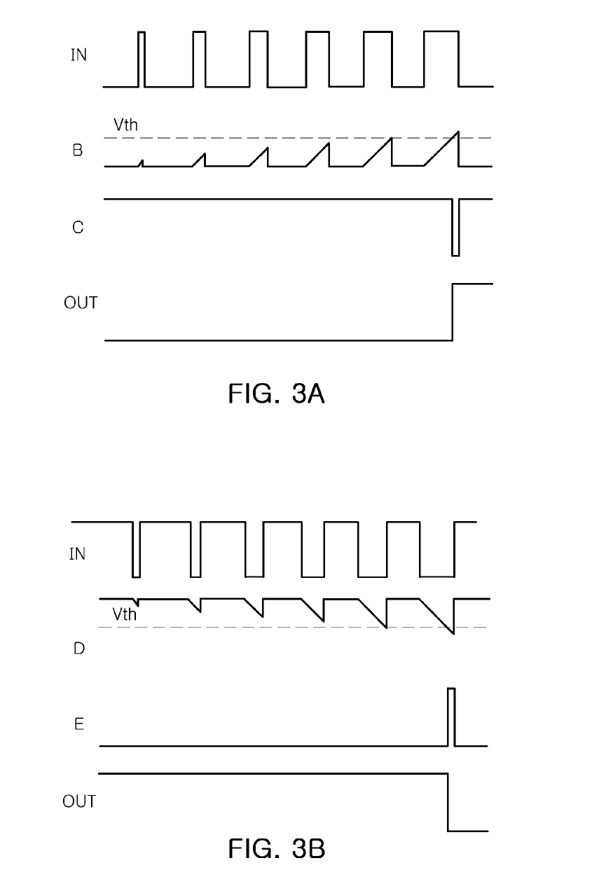

FIG. 3A is a view illustrating operational waveforms with respect to high noise in case in which an input signal has a low level.

FIG. 3B is a view illustrating operational waveforms with respect to low noise in case in which an input signal has a high level.

An operation of the driving circuit 100 according to an embodiment of the present invention will be described in detail with reference to FIGS. 1 through 3.

The first delay unit 111 may cancel high noise generated when an input signal is maintained in a low level state. Namely, as illustrated in FIG. 2, a node C (please see FIG. 1) may be maintained to have a high value until an input signal IN has a high level having a pulse width equal to or greater than a predetermined value, and when a voltage in a node B (please see FIG. 1) exceeds a pre-set high level voltage Vth, the input signal may be recognized as a normal signal, rather than as noise. Thus, the voltage in the node C is changed from the high level to a low level and the first transistor M1 is turned on to output a high level signal.

Referring to FIG. 3A, it can be seen that when the voltage in the node B exceeds the pre-set high level voltage Vth, a voltage in the node C is changed to have a low level. Also, accordingly, it can be seen that the first transistor M1 is turned on to output a high level signal.

Namely, by charging voltages to the first capacitor C1, the first delay unit 111 may delay the input signal IN by an amount of time required for the voltage in the node B to exceed the pre-set high level voltage Vth.

The second delay unit 112 may cancel low noise generated when the input signal is maintained in a high level state. Namely, as illustrated in FIG. 2, a node E (please see FIG. 1) is maintained to have a low value until the input signal IN has a low level having a pulse width equal to or greater than a predetermined value, and when a voltage in the node D (please see FIG. 1) is less than the pre-set low level voltage Vth, the input signal may be recognized as a normal signal, rather than as noise. Thus, the voltage in the node E is changed from the low level to a high level and the second transistor M2 is turned to output a low level signal.

Referring to FIG. 3B, it can be seen that when a voltage of the node D is less than the pre-set low level voltage Vth, a voltage in the node E is changed to have a high level. Also, accordingly, it can be seen that the second transistor M2 is turned on to output a low level signal.

Namely, by discharging voltages from the second capacitor C2, the second delay unit 112 may delay the input signal IN by an amount of time required for the voltage in the node D to have a level less than the pre-set low level voltage Vth.

Also, when the input signal has a low level, the first delay unit 111 may output the low level input signal without a delay to control a turn-off operation of the first transistor M1. When the input signal has a high level, the second delay unit 112 may output the high level input signal without a delay to control a turn-off operation of the second transistor M2.

As a result, only input signals for turning on the first and second transistors M1 and M2 are delayed, and thus, the first and second transistors M1 and M2 may be simultaneously turned off in some cases.

Here, immediately before the first and second transistors M1 and M2 are turned off, namely, only when the input signal is changed, the output holding unit 130 may maintain an output voltage, and when the input signal is maintained in a high level state or a low level state, an output voltage may not be affected.

In this manner, the driving circuit 100 according to an embodiment of the present invention may effectively filter low level noise superposed on a high level signal input and high level noise superposed on a low level signal input.

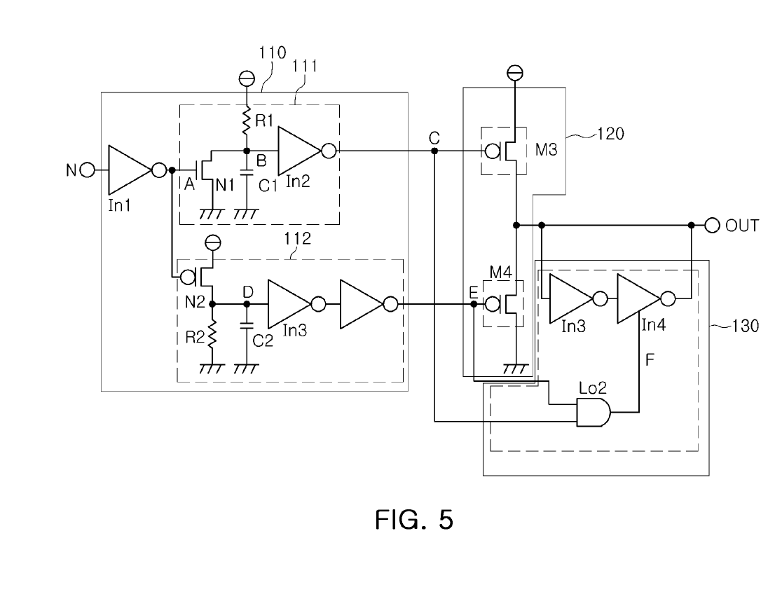

FIG. 5 is a circuit diagram of the driving circuit 100 according to another embodiment of the present invention.

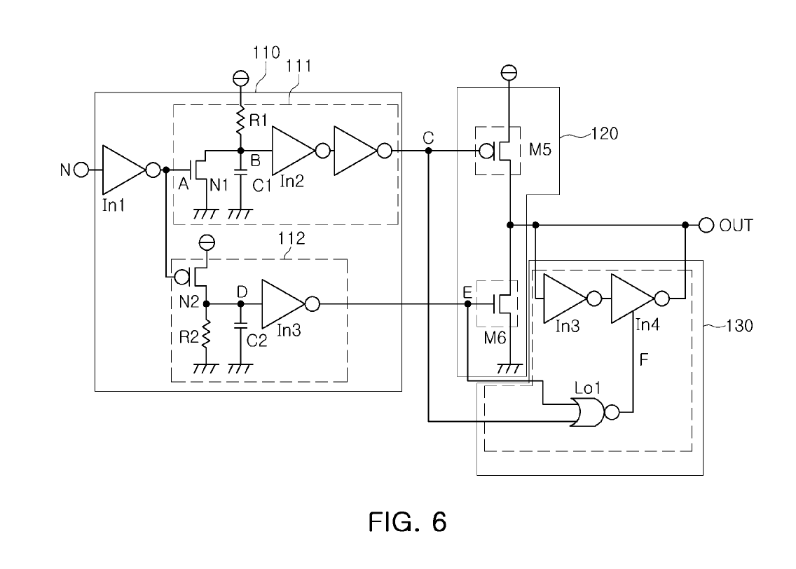

FIG. 6 is a circuit diagram of the driving circuit 100 according to another embodiment of the present invention.

Referring to FIGS. 5 and 6, at least one inverter may be added to the first and second delay units 111 and 112. In this case, a combination of the first and second transistors M1 and M2 of the signal output unit 120 may vary according to the amount of added inverters and in which of the first and second delay units 111 and 112 the inverter(s) is/are added.

It is obvious that, besides the configuration according to the present embodiment, the configuration may vary within a range in which it satisfies the conditions that the first and second transistors M1 and M2 are simultaneously turned off as described above.

FIG. 5 illustrates a configuration in which an inverter is added in series to the third inverter In3 of the second delay unit 112, and thus, a fourth transistor M4 may be configured to be the same as a third transistor M3, namely, as a PMOS transistor. Also, the output holding unit 130 may include an AND latch circuit Lo2, without the fifth inverter In5 (please see FIG. 1).

FIG. 6 illustrates a configuration in which an inverter is added to the second inverter In2 of the first delay unit 111 in series, and thus, a fifth transistor M5 may be configured to be the same as a sixth transistor M6, namely, as an NMOS transistor. Also, the output holding unit 130 may be configured without the fifth inverter In5 (please see FIG. 1).

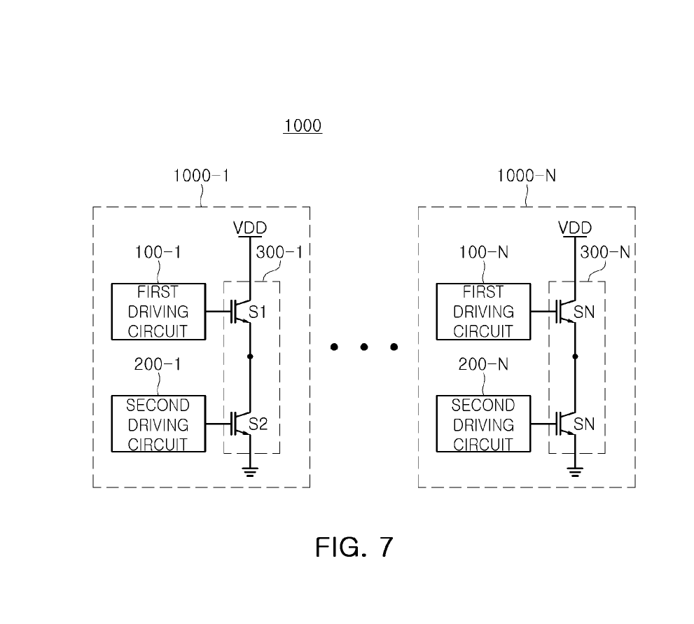

FIG. 7 is a schematic view illustrating a configuration of a driving module 1000 according to an embodiment of the present invention. The driving circuit 100 illustrated in FIG. 1 according to an embodiment of the present invention may form the driving module together with a switch, as illustrated in FIG. 7.

The foregoing driving module may include a switching unit 300-1 having at least two transistors S1 and S2 stacked between an operating power source terminal supplying operating power VDD and a ground and first and second driving circuits 100-1 and 100-2 driving the two transistors S1 and S2, respectively, and a plurality of unit circuits 1000-1 may be provided.

Descriptions of the first and second driving circuits 100-1 and 200-1 are the same as those above with reference to FIGS. 1 through 6, so a detailed description thereof will be omitted.

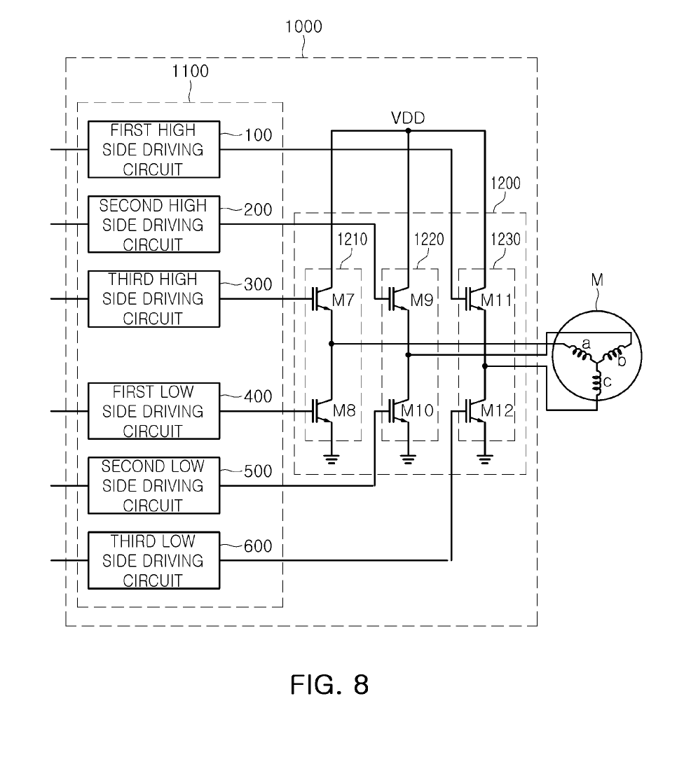

FIG. 8 is a schematic view illustrating a configuration of a motor driving apparatus according to an embodiment of the present invention.

The driving module illustrated in FIG. 8 may be used in a motor driving apparatus, and to this end, the motor driving apparatus may include an inverter 1200 for driving a motor M and a driving circuit group 1100.

The inverter 1200 and the driving circuit group 1100 may constitute a driving module. When the motor M is a 3-phase (a, b, c) motor, the inverter 120 may include 3-phase inverter arms 1210, 1220, and 1230, and the first to third inverter arms 1210, 1220, and 1230 may have at least two first and second semiconductor elements M7 and M8, M9 and M10, and M11 and M12 stacked between an operating power source terminal and a ground, respectively.

Here, in an embodiment, the first semiconductor element may be a PMOS transistor, and the second semiconductor element may be an NMOS transistor.

The driving circuit group 1100 may include first to third high side driving circuits 100, 200, and 300, and first to third low side driving circuits 400, 500, and 600. The first to third high side driving circuits 100, 200, and 300 may drive the high side transistors M7, M9, and M11 of the first to third inverter arms 1210, 1220, and 1230, respectively, and the first to third low side driving circuits 400, 500, and 600 may drive the low side transistors M8, M10, and M12 of the first to third inverter arms 1210, 1220, and 1230, respectively.

Operations and configurations of the first to third high side driving circuits 100, 200, and 300, and the first to third low side driving circuits 400, 500, and 600 are the same as the components and operations illustrated in

FIGS. 1 through 6, so a detailed description thereof will be omitted.

As set forth above, according to embodiments of the invention, low level noise superposed on a high signal input and high level noise superposed on a low signal input of a the semiconductor circuit can be effectively filtered.

While the present invention has been shown and described in connection with the embodiments, it will be apparent to those skilled in the art that modifications and variations can be made without departing from the spirit and scope of the invention as defined by the appended claims.

What is claimed is:

1. A driving circuit comprising:
a signal delay unit including a first delay unit delaying a high level input signal in a case in which an input signal has a high level, and a second delay unit delaying a low level input signal when the input signal has a low level;
a signal output unit including first and second transistors connected to the first and second delay units and performing a switching operation under the control of the first and second delay units, respectively; and
an output holding unit maintaining an output voltage at a level equal to that immediately before the first and second transistors are turned off, when the first and second transistors are simultaneously turned off.

2. The driving circuit of claim 1, wherein the signal delay unit further includes at least one inverter inverting the input signal and providing the inverted signal to the first and second delay units.

3. The driving circuit of claim 1, wherein the first delay unit delays the input signal by an amount of time required for the first delay unit to have a voltage charged to reach a level equal to or higher than a pre-set high level voltage.

4. The driving circuit of claim 1, wherein the second delay unit delays the input signal by an amount of time required for the second delay unit to have a voltage discharged to reach a level lower than a pre-set low level voltage.

5. The driving circuit of claim 1, wherein the first and second delay units further include at least one switching element, at least one inverter, and at least one delay element for generating a delay.

6. The driving circuit of claim 1, wherein the output holding unit includes at least one inverter and at least one latch circuit.

7. A driving circuit comprising:
a first inverter inverting an input signal;
a first delay unit delaying a first signal received from the first inverter until a voltage of a first capacitor reaches a level equal to or higher than a pre-set high level;
a second delay unit delaying a second signal received from the first inverter until when a voltage of a second capacitor is discharged to have a level lower than a pre-set low level;
a signal output unit including first and second transistors connected to the first and second delay units and performing a switching operation under the control of the first and second delay units, respectively; and
an output holding unit maintaining an output voltage at a level equal to that immediately before the first and second transistors are turned off when the first and second transistors are simultaneously turned off.

8. The driving circuit of claim 7, wherein the first signal is a low level signal, and the second signal is a high level signal.

9. The driving circuit of claim 7, wherein the first delay unit controls a turn-on operation of the first transistor by using the delayed first signal.

10. The driving circuit of claim 7, wherein the second delay unit controls a turn-on operation of the second transistor by using the delayed second signal.

11. The driving circuit of claim 7, wherein when the second signal is received from the first inverter, the first delay unit controls a turn-off operation of the first transistor without a delay.

12. The driving circuit of claim 7, wherein when the first signal is received from the first inverter, the second delay unit controls a turn-off operation of the second transistor without a delay.

13. The driving circuit of claim 7, wherein the first and second delay units further include at least one switching element, at least one inverter, and at least one delay element for generating a delay, respectively.

14. The driving circuit of claim 7, wherein the output holding unit includes at least one inverter and at least one latch circuit.

15. The driving circuit of claim 7, wherein the at least one delay element includes a resistor connected to the second capacitor.

16. A driving module comprising:
at least one driving circuit including a signal delay unit including a first delay unit delaying a high level input signal in a case in which an input signal has a high level, and a second delay unit delaying a low level input signal when the input signal has a low level, a signal output unit including first and second transistors connected to the first and second delay units and performing a switching operation under the control of the first and second delay units, respectively, and an output holding unit maintaining an output voltage at a level equal to that immediately before the first and second transistors are turned off, when the first and second transistors are simultaneously turned off; and a switching unit having a semiconductor element switched on and switched off according to a driving signal from the at least one driving circuit.

17. The driving module of claim 16, wherein the switching unit includes at least two semiconductor elements stacked between an operating power source terminal and a ground.

18. The driving module of claim 17, further comprising first and second driving circuits driving the semiconductor elements, respectively.

19. A motor driving apparatus comprising:
a driving circuit group including a plurality of driving circuits each including a signal delay unit including a first delay unit delaying a high level input signal in a case in which an input signal has a high level, and a second delay unit delaying a low level input signal when the input signal has a low level, a signal output unit including first and second transistors connected to the first and second delay units and performing a switching operation under the control of the first and second delay units, respectively, and an output holding unit maintaining an output voltage at a level equal to that immediately before the first and second transistors are turned off, when the first and second transistors are simultaneously turned off; and
an inverter driving a motor by using inverter arms included therein, each of the inverter arms having a semiconductor element switched on or switched off according to driving signal from each of the plurality of driving circuits of the driving circuit group.

20. The motor driving apparatus of claim 19, wherein the inverter includes 3-phase inverter arms in which at least one first semiconductor element and at least one second semiconductor element are stacked, respectively.

21. The motor driving apparatus of claim 19, wherein the driving circuit group comprises:
a plurality of high side driving circuits driving the first semiconductor elements of the 3-phase inverter arms, respectively; and
a plurality of low side driving circuits driving the second semiconductor elements of the 3-phase inverter arms, respectively.
